(19) United States
(12) Patent Application Publication
(10) Pub. No.: US 2026/0087216 A1
(43) Pub. Date: Mar. 26, 2026

(54) AN EMULATION SYSTEM HAVING PLATFORM DEVICE AND INTEGRATED CIRCUIT DEVICE REDUNDANCY

(71) Applicant: XILINX, INC., San Jose, CA (US)

(72) Inventors: Tauheed ASHRAF, San Jose, CA (US); Raghukul Bhushan DIKSHIT, San Jose, CA (US); Carsten HOFFMANN, San Jose, CA (US); Catherine WARREN, San Jose, CA (US)

(21) Appl. No.: 18/898,111

(22) Filed: Sep. 26, 2024

(51) Int. Cl. G06F 30/33; G06F 9/455

(52) U.S. Cl. CPC G06F 30/33; G06F 9/455

(57) ABSTRACT

An emulation system includes a first platform device, a second platform device, and a processing device. The first platform device includes first integrated circuit (IC) devices. The first IC devices emulate a circuit design for verification of the circuit design. The second platform device includes second IC devices. The processing device connected to the first platform device and the second platform device. The processing device configured to emulate the circuit design using one or more of the second IC devices based on a failure associated with the first platform device being detected.

### TECHNICAL FIELD

This disclosure relates to an emulation system that includes redundant platform devices and/or integrated circuit (IC) devices that are used when a failure in a platform device and/or IC device is detected.

### BACKGROUND

Some emulation systems use multiple integrated circuit (IC) devices to provide in-circuit emulation of circuit designs. Often, the IC devices are programmable IC devices such as Field Programmable Gate Arrays (FPGAs). For such an emulation system, silicon components of the circuit design to be emulated are synthesized and mapped to equivalent hardware resources on the IC devices of the emulation system. In most cases, since the circuit design does not fit within a single IC device, the circuit design is ported over and partitioned for implementation across the multiple IC devices of the emulation system. Typically, each IC device of the emulation system shares inputs/outputs (I/Os) with multiple other IC devices.

An emulation system (or prototyping platform) may be deployed as part of a datacenter (e.g., enterprise prototyping or an emulation platform). Such an emulation system may include multiple platforms (e.g., a chassis, units, or building blocks). The platforms may be identical and include multiple IC devices.

In an emulation system for large scale IC device (e.g., system-on-chip, among others) prototyping, standard input/output transceivers or Multi-Gigabit-Transceivers (MGTs) are used to connect the platforms to each other. During the emulation process, a platform device and/or IC device may fail. Failure of a platform device may result in the corresponding emulation to fail and replacement of the platform device and/or one or more IC devices. Replacement of the platform device and/or one or more IC devices may require that the design of the IC device be re-compiled based on the changes to the emulation system as the connections between the IC devices differ, the connections between the platform devices, the configuration of the IC devices, and/or the configuration of the platform devices may differ.

### SUMMARY

In one example, an emulation system includes a first platform device, a second platform device, and a processing device. The first platform device includes first integrated circuit (IC) devices. The first IC devices emulate a circuit design for verification of the circuit design. The second platform device includes second IC devices. The processing device connected to the first platform device and the second platform device. The processing device configured to emulate the circuit design using one or more of the second IC devices based on a failure associated with the first platform device being detected.

In one example, a method includes detecting a failure in a first platform device of an emulation system. The emulation system emulates a circuit design for verification of the circuit design. The method further includes disconnecting the first platform device from a second platform device of the emulation system based on detecting the failure. Further, the method includes connecting the second platform device to a third platform device of the emulation system. The circuit design is emulated using the second platform device and the third platform device.

In one example, an emulation system includes a first platform device, a second platform device, and a third platform device. Further, the emulation system includes interconnection circuitry that connects the first platform device, the second platform device, and the third platform device with each other. The emulation system further includes a processing device connected to the first platform device, the second platform device, and the third platform device. The processing device performs a first emulation of a circuit design by outputting emulation data to the first platform device and the second platform device. Further, the processing device stops the first emulation and performs a second emulation of the circuit design by outputting the emulation data to the second platform device and the third platform device based on a failure associated with the first platform device being detected.

### BRIEF DESCRIPTION OF THE DRAWINGS

The inventive arrangements are illustrated by way of example in the accompanying drawings. The drawings, however, should not be construed to be limiting of the inventive arrangements to only the particular implementations shown. Various aspects and advantages will become apparent upon review of the following detailed description and upon reference to the drawings.

FIG. 1 illustrates an example of an emulation system having redundancy.

FIG. 2 illustrates a block diagram of an example of an emulation system having a redundant platform device and IC devices connected via an interconnect circuitry having switching circuitries.

FIG. 3 illustrates a block diagram of an example of an emulation system having a redundant platform device and IC devices having switching circuities connected via an interconnect circuitry.

FIG. 4 illustrates a block diagram of an example of an emulation system having a redundant platform device and IC devices connected via an interconnect circuitry.

FIG. 5 illustrates a flowchart of a method for detecting and mitigating failures within an emulation system.

FIG. 6 illustrates a block diagram of the platform devices of an emulation system.

FIG. 7 illustrates a block diagram of the platform devices having a failed platform device.

FIG. 8 illustrates a block diagram of an emulation system having a replaced platform device.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Circuit designs are emulated to verify the functionality of the circuit designs. An emulation system is used to emulate the circuit designs. An emulation system includes multiple platform devices. Each of the platform devices includes one or more integrated circuit (IC) devices. A platform device is a building block of the emulation system. Each platform device may have a similar configuration of IC devices (e.g., same number and/or type). The IC devices may be programmable IC devices. For example, an IC device may be a Field Programmable Gate Array (FPGA).

The platform devices are interconnected. Further, the IC devices within a platform device and between platform devices are interconnected. The platform devices may be interconnected via interconnection circuitry. The interconnection circuitry may be optical interconnect circuitry. Emulation systems that include multiple platform devices and multiple IC devices may be used to emulate and verify large circuit designs. Large circuit designs include circuit designs for Systems-on-Chips (SoCs). In one example, emulation systems as described herein are used in enterprise prototyping and/or emulation platforms. For example, the emulation systems as described herein may be part of a datacenter that includes multiple interconnected emulation systems.

During an emulation process, one or more platform devices and/or IC devices of an emulation system may fail. The failure is detected by a processing device of the emulation system. The emulation process of a circuit design fails when there is a failure of a platform device and/or IC device. In one example, the emulation system includes one or more redundancy platform devices including one or more redundancy IC devices. A failed platform device and/or the failed IC device are replaced with a redundant platform device and/or an IC device of a redundant platform device. After a failed platform device or failed IC device is replaced with a corresponding redundant platform device or IC device, the emulation and verification process of a circuit design is completed. A redundant platform device or a redundant IC device is connected to the other platform devices or IC devices, taking the place of a failed platform device or IC device used during the emulation and verification process. The failed platform device or IC device may then be replaced within the emulation system. The emulation systems that support redundancy as described herein simplify emulation platform deployment, serviceability of an emulation system or an emulation platform, and/or decreases downtown of the emulation system as compared to emulation systems that do not support redundancy.

In the following, an improved emulation system is described that includes redundancy. The redundancy includes one or more redundant platform devices and/or redundant IC devices that are connected via an interconnection circuitry. The redundancy allows for a redundant platform device and/or redundant IC device to be used to replace a failed platform device or a failed IC device, simplifying platform deployment and serviceability, and decrease downtime of the emulation system.

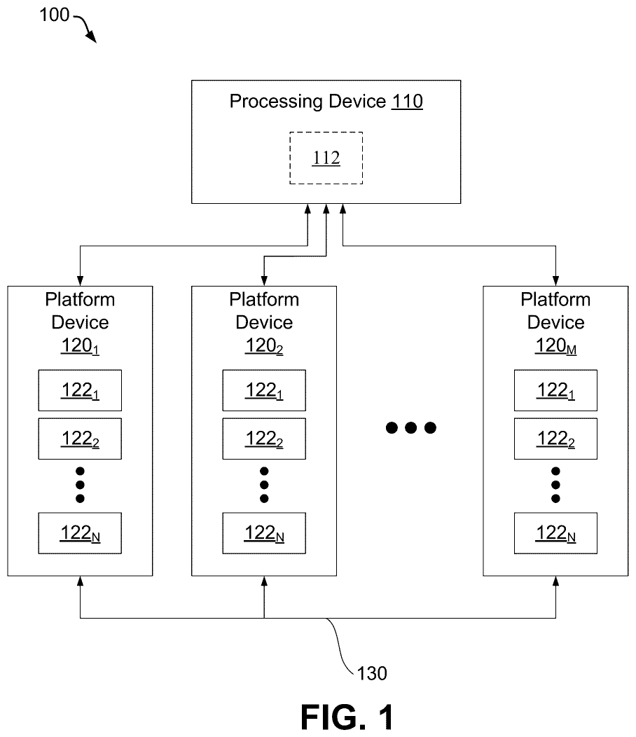

FIG. 1 depicts a block diagram of an emulation system 100. The emulation system 100 may be configured to verify the functionality of the circuit design. The emulation system 100 may include a processing device 110 and platform devices 120. The emulation system 100 is used to emulate a circuit design during the verification of the functionality of the circuit design. In one example, the circuit design is compiled by the emulation system 100 to determine functions to be performed by the platform devices 120.

In one example, the emulation system 100 is part of a distributed computer system. For example, the emulation system 100 is connected to one or more other emulation systems or other types of computer systems. For example, the emulation system 100 includes network interface circuitry that is used to communicate data between each of the emulations systems and/or computer systems within the distributed computer system. In a distributed computer system, the emulation system 100 may be referred to as a server. When included within a distributed computer system, each of the interconnected emulation systems and/or computer systems perform one or more functions of a shared operation.

The processing device 110 includes one or more processors. The processing device 110 may be a central processing unit (CPU) or a graphics processing unit (GPU), among others. In one example, the processing device 110 obtains (e.g., receives) emulation data (configuration data) associated a circuit design from a memory. In one example, the configuration data is a binary data or a bitstream. The emulation data is generated from the circuit design. In one example, a description language may be used to represent the circuit design. The circuit design is compiled to generate the emulation data to be performed by the platform devices 120 to emulate the circuit design. The emulation process is distributed amongst the platform devices 120. During the compiling process, the circuit design is transformed, changed, and/or restructured, new functions may be added, and/or control the timing of the circuit design is generated. In one example, the compiling process is performed external to the emulation system 100. In such an example, the processing device 110 obtains the emulation data from the system or processing device that is external to the emulation system 100. For example, the emulation data may be stored in a memory device that is external or internal to the emulation system 100. The processing device 110 obtains the emulation data from the memory. In another example, the compiling process is performed by a processing device within the emulation system 100 and external to the processing device 110 to generate the emulation data. The emulation data is stored within a memory device of the emulation system 100 and accessed by the processing device 110.

The processing device 110 is connected to each of the platform devices 120. The processing device 110 provides emulation data to the platform devices 120 to perform the emulation process of the circuit design. Further data determined during the emulation process by the platform devices 120 is provided to the processing device 110.

The emulation system 100 includes platform devices 120₁-120_{M}. M is one or more. The platform devices 120₁-120_{M} are interconnected. For example, the platform devices 120₁-120_{M} are interconnected via the interconnection circuitry 130. Each of the platform devices 120₁-120_{M} is able to communicate with each other of the platform devices 120₁-120_{M}. Each platform device 120 includes one or more IC devices 122.

The platform devices 120 include a housing in which the IC devices 122 are disposed. Further, a platform device 120 includes one or more connection devices (e.g., boards or substrates) on which the IC devices 122 are mounted and interconnected within the platform device 120. In one or more examples, a platform device 120 includes a bus or other connection circuitry that is used to interconnect the IC devices 122 within the platform device 120.

In one or more examples, the IC devices 122 are programmable IC devices. For example, the IC devices 122 are FPGAs, application specific IC (ASIC) devices, and/or other programmable IC devices. Within each platform device 120, the IC devices 122 are interconnected. Further, the IC devices 122 of a platform device 120 are connected to an output or outputs of the platform device 120.

An IC device 122 can include one or more input/output interfaces used to connect an IC device 122 with the other IC devices 122 to communicate signals between the IC devices 122. An FPGA interface can be referred to as an input/output pin or an FPGA pad.

A programmable IC device includes programmable logic blocks and interconnections that connect the programmable logic blocks based compiled code of the circuit design under test. A programmable logic block performs binary, logic gate functions, and/or memory operation functions, among others.

Each platform device 120 includes IC devices 122₁-122_{N}. N is two or more. As illustrated in FIG. 1, each platform device 120 includes the same number of IC devices 122. In other examples, at least one platform device 120 includes a different number of IC device 122 than another one of the platform devices 120.

The processing device 110 communicates emulation data (e.g., the compiled code of circuit design under test) to one or more of the platform devices 120. Further, the platform devices 120 output data generated based on performing the operations corresponding to the emulation data to the processing device 110. The platform device 120 may be connected to the processing device 110 via one or more traces connected to input/output pins of the platform device 120 and the processing device 110.

The platform devices 120 are connected to each other via the interconnection circuitry 130. The interconnection circuitry 130 includes electrical interfaces and connections. The interconnection circuitry 130 additionally, or alternatively, includes optical interfaces and connections. In one example, the interconnection circuitry 130 may be referred to as an optical interconnection circuitry 130. Further, the interconnection circuitry 130 may be a crossbar network. In one example, the IC devices 122 of each platform device 120 are connected to the interconnection circuitry 130 via one or more input/output pins of the corresponding platform device 120. Within a platform device 120, the IC devices 122 are interconnected with each other and connected to the input/output pins of the platform device 120 via electrical connections.

In one example, the platform devices 120 are symmetric. For example, the platform devices 120 are symmetrically connected within the emulation system 100. Further, the platform devices include the same number of IC devices 122, the same type of IC devices 122, and/or the same configuration of IC devices 122. In one or more examples, symmetrically connected platform devices 120 within the emulation system 100 include platform circuities that are connected to each other platform device within the platform devices 120. Symmetrically connected platform devices 120 include platform circuities that are able to communicate signals (e.g., transmit and receive) with each other platform device within the platform devices 120. The platform devices 120 are connected to each other and communicate with each other via the interconnection circuitry 130.

IC devices 122 within a platform device 120 are symmetrically connected with each other. For example, each IC device 122 of a platform device 120 is connected to each other IC device 122 of the platform device 120. Further, each IC device 122 of a platform device 120 is able to communicate signals (e.g., transmit and receive) with each other IC device 122 of the platform device 120. The IC devices 122 of a platform device 120 are symmetrically connected with the IC devices 122 of each other platform device 120. For example, each IC device 122 of a platform device 120 is connected to each other IC device 122 of each other platform device 120 of the emulation system 100. Further, each IC device 122 of a platform device 120 is able to communicate signals (e.g., transmit and receive) with each other IC device 122 of each other platform device 120 of the emulation system 100 via the interconnection circuitry 130.

Further, due to the symmetric nature of the platform devices 120 and/or the IC devices 122 of the emulation system 100, emulation of a circuit design is able to be performed after the detection of a failed platform device and/or IC device without recompiling the circuit design, decreasing the emulation processing time and amount of time used to verify a circuit design.

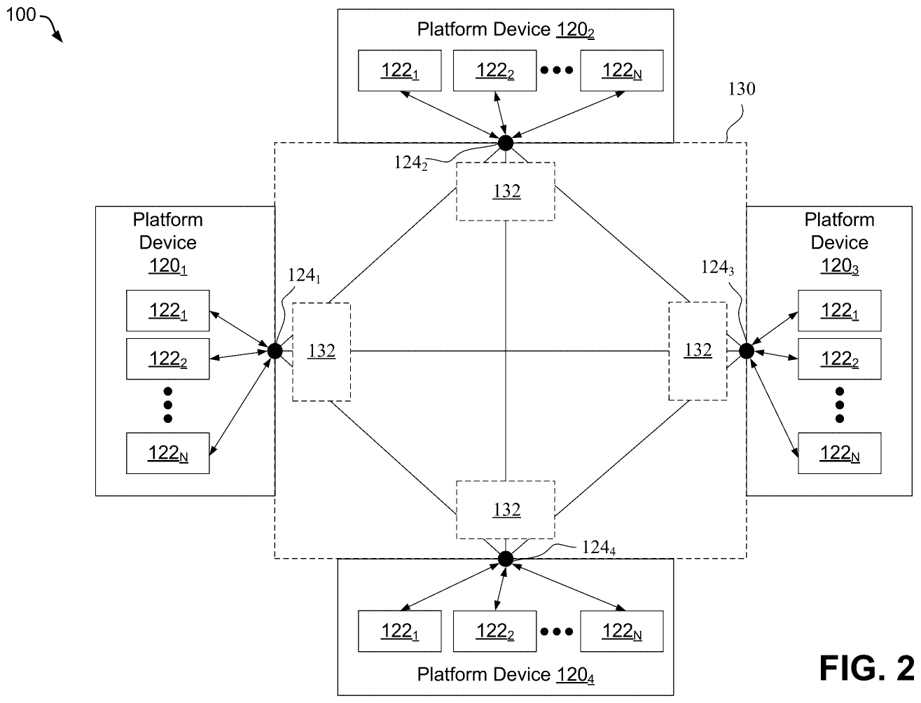

FIG. 2 illustrates an example where the interconnection circuitry 130 provides for symmetric connections between the platform devices 120 are symmetric. For example, the platform device 120₁ is connected to the platform devices 120₂, 120₃, and 120₄ via the interconnection circuitry 130. The platform device 120₂ is connected to the platform devices 120₁, 120₃, and 120₄ via the interconnection circuitry 130. The platform device 120₃ is connected to the platform devices 120₁, 120₂, and 120₄ via the interconnection circuitry 130. The platform device 120₄ is connected to the platform devices 120₁, 120₂, and 120₃ via the interconnection circuitry 130. Accordingly, each platform device 120₁, 120₂, 120₃, and 120₄ is connected to each other platform device.

The interconnect circuitry 130 includes optical connections that connect each of the platform devices 120 with each other. Each optical connection includes one or more optical cables (e.g., fiber cables) that connect two of the platform devices 120 with each other.

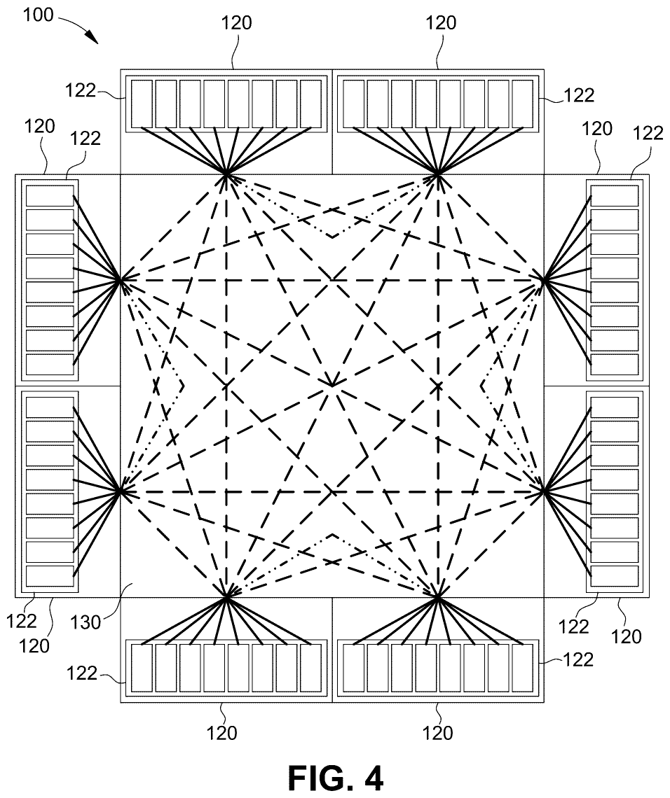

FIG. 4 illustrates an example where the interconnection circuitry 130 connects eight platform circuities with each other. One or more of the platform devices 120 are redundant platform devices. The interconnection circuitry 130 includes multiple optical connections that connect each platform device 120 together. A respective optical connection is used to connect pairs of the platform device 120, such that there is an independent connection between each pair of platform devices 120, and each platform device 120 is connected to each other platform device 120.

In one example, one or more of the platform devices 120 and the corresponding IC devices 122 are configured (or operated) as a redundant platform device 120 and redundant IC devices 122. A redundant platform device 120 is a platform device that is not actively used for the emulation process. A redundant platform device 120 may be swapped for a failed platform device 120, and used to perform the operations (e.g., the emulation operations) of the failed platform device 120. A redundant IC device 122 is an IC device that is not actively used for the emulation process. A redundant IC device 122 may be swapped for a failed IC device 122, and used to perform the operations (e.g., the emulation operations) of the failed IC device 122. The emulation operations correspond to portion of the circuit design that an IC device 122 and/or an IC platform performs to emulate a circuit design. The emulation operations may include logical operations. The logical operations include the simulation of logic gates. The logical operations are performed based on one or more input signals and/or one or more clock signals associated with the circuit design.

In one example, the processing device 110 detects one or more failures within the platform devices 120. The processing device 110 determines to and provides instructions to deactivate the failed platform device 120 and activate a redundant platform device 120 to perform the functions of the failed platform device 120. In one example, the processing device 110 is connected with each platform device 120. The processing device 110 determines a failure of the platform device 120₁. The processing device 110 communicates instructions to deactivate the platform device 120₁. For example, the platform devices 120₁ and 120₂ may be used to perform the emulation and verification of a circuit design under test. Accordingly, the platform device 120₁ and the platform device 120₂ are communicatively connected with each other. The platform device 120₁ and the platform device 120₂ communicate data back and forth between each other to perform the operations of the emulation and verification of the circuit design under test. Accordingly, connections within the interconnection circuitry 130 between the platform device 120₁ and the platform device 120₂ are used to communicate data between the platform device 120₁ and the platform device 120₂. When a failure is detected within the platform device 120₁ is detected, the platform device 120₁ is deactivated. For example, the processing device 110 detects failure within the platform device 120₁, and deactivates the platform device 120₁. In one example, deactivating the platform device 120₁ includes instructing the platform device 120₂ to communicate with the redundant platform device 120₃. Further, instructions are provided to the redundant platform device 120₃ to perform the emulation processes previously performed with the platform device 120₁ and to communicate with the platform device 120₂. Accordingly, connections within the interconnection circuitry 130 between the platform device 120₂ and the platform device 120₃ are used to communicate data between the platform device 120₂ and the platform device 120₃.

In one example, the processing device 110 detects one or more failures within the IC devices 122 of the platform devices 120. The processing device 110 determines to and provides instructions to deactivate the failed IC device 122 and activate a redundant IC device 122 to perform the functions of the failed IC device 122. In one example, the processing device 110 determines a failure of the IC device 122₁ of the platform device 120₁. The processing device 110 communicates instructions to deactivate the IC device 122₁ of the platform device 120₁. For example, the IC devices 122 platform devices 120₁ and 120₂ may be used to perform the emulation and verification process of a circuit design under test. Accordingly, the IC devices 122 of platform device 120₁ and the IC devices 122 of the platform device 120₂ are communicatively connected with each other. The IC devices 122 of the platform device 120₁ and the IC devices 12 of the platform device 120₂ communicate between each other to perform the operations of the emulation and verification process of the circuit design under test. Accordingly, connections within the interconnection circuitry 130 between the IC devices 122 of platform device 120₁ and the IC devices 122 of the platform device 120₂ are used to communicate data between the IC devices 122 of the platform device 120₁ and the IC devices 122 of the platform device 120₂. When a failure is detected within the IC device 122₁ of the platform device 120₁ is detected, the IC device 122₁ of the platform device 120₁ is deactivated. For example, the processing device 110 detects a failure within the platform device 120₁, and deactivates the platform device 120₁. In one example, deactivating the IC device 122₁ of the platform device 120₁ includes instructing other IC devices 122 of the platform device 120₁ and/or the IC devices 122 of platform device 120₂ to communicate with the redundant IC device 122₁ of the redundant platform device 120₃. Further, instructions are provided to the redundant IC device 122₁ of the redundant platform device 120₃ to perform the emulation processes previously performed with IC device 122₁ of the platform device 120₁ and to communicate with the other IC devices 122 of the platform device 120₁ and/or the IC devices 122 of the platform device 120₂.

Failures include data traffic failures, data integrity issues, and/or connection issues, among others. A data traffic failure may be caused by a power loss of one or more IC devices 122 and/or platform devices 120. In one or more examples, a data traffic failure may be caused by an error in programing one or more IC devices 122. For example, there may be an error in receiving a bitstream for programming an IC device 122 and/or an error may occur when programming an IC device 122 with the bitstream. A data integrity issue may occur when data provided from one IC device 122 is not accurately received by another IC device 122. A data integrity issue may occur due to the optical connection between two IC devices 122. A connection issue may occur between two IC devices 122 due to a faulty optical cable or connector between the IC devices 122, or a fault within a transceiver device of one or more IC devices 122.

The processing device 110 detects failures within the emulation system 100. For example, the processing device 110 includes failure detection circuitry 112 that communicates with each of the platform devices 120 and the IC devices 122 to detect failures within the platform devices 120 and the IC devices 122. Failure detection may occur before and/or during the emulation and verification process of a circuit design under test. In one or more examples, test signals are output from the failure detection circuitry 112 to each of the platform devices 120 and the IC devices 122, communicated between two or more of the platform devices 120 and/or two or more of the IC devices 122, and communicated back to the failure detection circuitry 112 to detect failures within the emulation system 100. Data received at the failure detection circuitry 112 is compared to the expected data to determine failures are present within the emulation system. When the received data does not match the expected data, failures are determined to be present within the emulation system 100. In on example, a test signal has one or more target platform devices 120 and/or IC devices 122 that communicate the test signals between each other. The location of the failure corresponds to the target of the test signal. In one example, the test signals may be used to test the connections between platform devices 120 and/or between IC devices 122, the data integrity between platform devices 120 and/or between IC devices 122, and the data traffic between platform devices 120 and/or between IC devices 122 to determine corresponding faults.

In one or more examples, while the failure detection circuitry 112 is described as being included within the processing device 110, the failure detection circuitry 112 may be alternatively included within one or more of the platform devices 120, one or more of the IC devices 122, or external to the processing device 110, the platform devices 120 and the IC devices 122.

In the example of FIG. 2, each IC device 122 of a platform device 120 is connected to the input/output pins of the platform device 120. The input/output pins are represented by a common node 124 for each platform device 120. The node 124 of each platform device 120 is an input and output node, and is used to receive and transmit signals. The nodes 124 are connected to the interconnection circuitry 130. For example, each node 124 is connected to one or more optical connections of the interconnection circuitry 130. The node 124 of a platform device 120 is connected to the node 124 of each other platform device 120.

The interconnection circuitry 130 of FIG. 2 includes one or more switching circuitries 132. A switching circuitry 132 is an optical switch or an electrical switch. The switching circuitry 132 controls the connections (e.g., data signal connections) between platform devices 120. In one example, a switching circuitry 132 is used to disconnect a platform device 120 from a failed platform device 120 to a redundant platform device 120. For example, the platform devices 120₁ and 120₂ are connected with the platform device 120₃. The platform device 120₄ is a redundant platform device. Based on detecting an error at the platform device 120₃, the switching circuitry, or circuitries, 132, disconnect the platform devices 120₁ and 120₂ from the platform device 120₃, and connect the platform devices 120₁ and 120₂ to the redundant platform device 120₄.

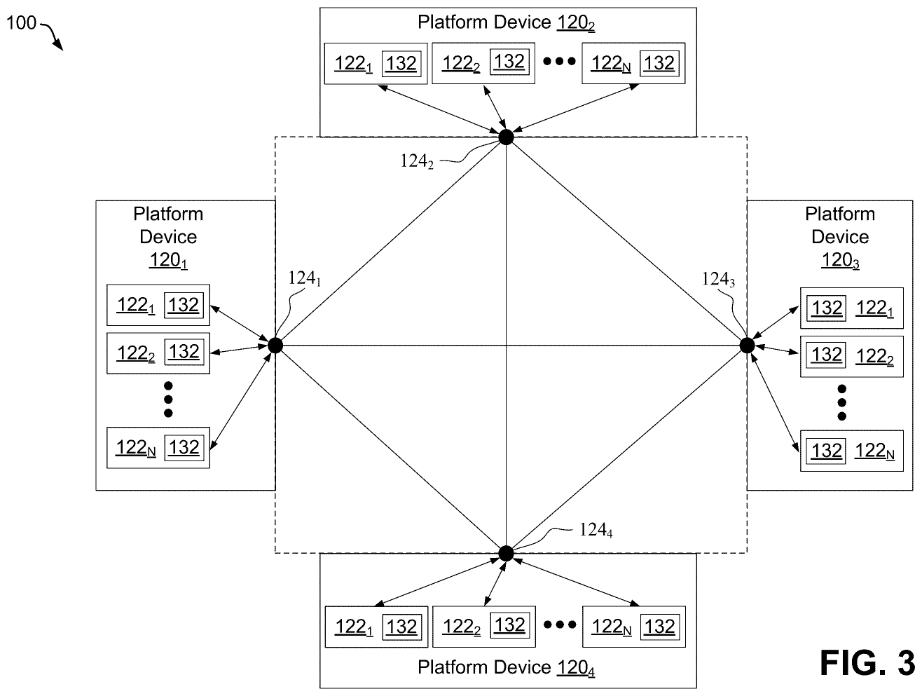

In the example of FIG. 3, each IC device 122 includes a respective switching circuitry 132. The switching circuitry 132 is internal to each of the IC devices 122. The switching circuitry 132 functions to control the connections between the IC devices 122 within each platform device 120 and between IC devices 122 of different platform device 120. For example, the switching circuitry 132 of the IC device 122₁ of the platform device 120₁ controls connections between the IC devices 122₂-122_{N} of the platform device 120₁ and the IC device 122₁ of the platform device 120₁. For example, register values associated with the switching circuitry 132 of the IC device 122₁ of the platform device 120₁ are set to connect the IC device 122₁ of the platform device 120₁ with one or more of the IC devices 122₂-122_{N} of the platform device 120₁. Further, the switching circuitry 132 of an IC device 122 controls the connections (e.g., data signal connections) between that IC device 122 and each other IC device 122 of the emulation system 100. For example, the switching circuitry 132 of the IC device 122₁ of the platform device 120₁ controls connections between the IC device 122₁ of the platform device and the IC devices 122 of the platform devices 120₂-120₄. For example, register values associated with the switching circuitry 132 of the IC device 122₁ of the platform device 120₁ are set to connect the IC device 120₁ of the platform device 120₁ with one or more of the IC devices 122 of the platform devices 120₂-120₄.

In one example, the switching circuitries 132 of the IC devices 122₁ and 122₂ of the platform device 120₁ are set to connect the IC devices with each other. Based on the detection of a failure at the IC device 122₂, the switching circuitry 132 of the IC device 122₁ of the platform device 120₁ is set to connect the IC device 122₁ of the platform device 120₁ with the IC device 122₁ of the platform device 120₄, as the IC device 122₁ of the platform device 120₄ is a redundant IC device. Further, the switching circuitry 132 of the IC device 122₁ of the platform device 120₄ is set (updated) to connect the IC device 122₁ of the platform device 120₄ with IC device 122₁ of the platform device 120₁.

In one example, the switching circuitries 132 of the IC devices 122 of the platform device 120₁ are set to connect the IC devices 122 of the platform device 120₁ with the IC devices 122 of the platform device 120₂. Based on the detection of a failure at the platform device 120₂, the switching circuitries 132 of the IC devices 122 of the platform device 120₁ are set to connect the IC devices 122 of the platform device 120₁ with the IC devices 122 of the platform device 120₄, as the platform device 120₄ is a redundant platform device. Further, the switching circuitries 132 of the IC devices 122 of the platform device 120₄ are set (updated) to connect the IC devices 122 of the platform device 120₄ with IC devices 122 of the platform device 120₁.

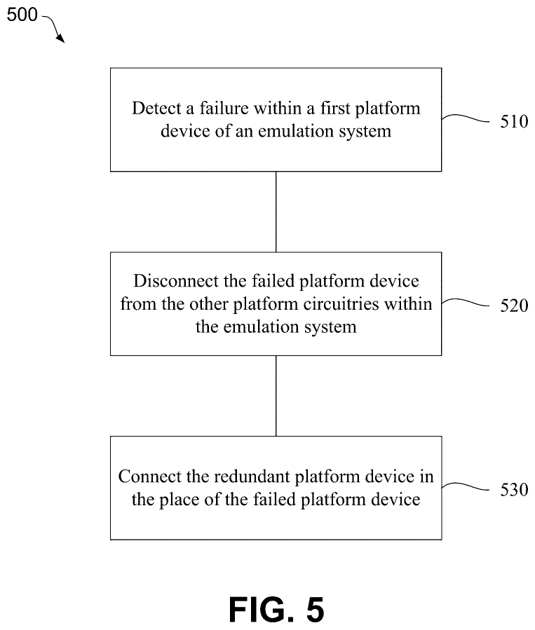

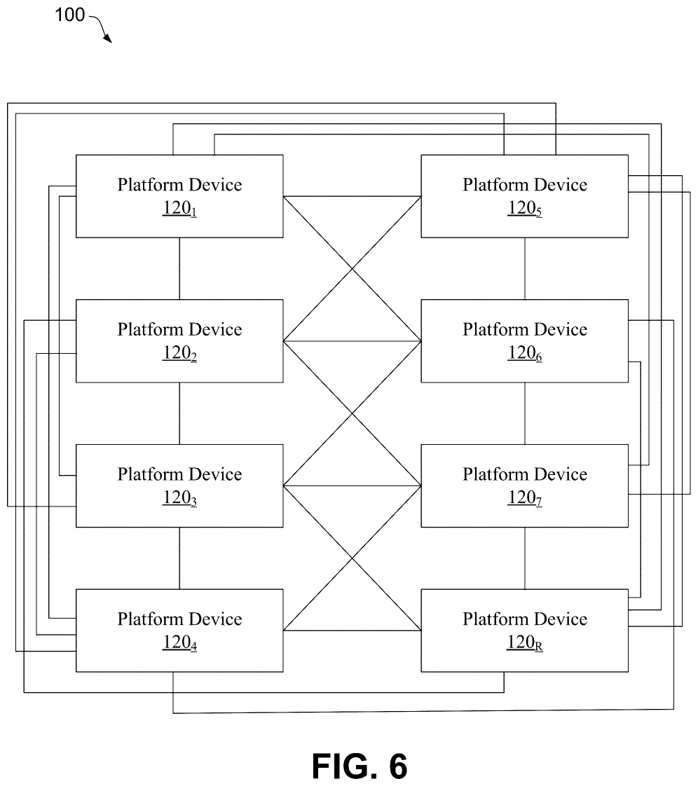

FIG. 5 illustrates a flowchart of a method 500 for detecting and mitigating a failure of a platform device within an emulation system. At 510 of the method 500, a failure is detected within a first platform device. In one example, the processing device 110 of FIG. 1 detects a failure. In another example, the failure detection circuitry 112 of FIG. 1 detects a failure. In one example with reference to FIG. 6, a failure is detected within platform device 120₆. The connection between each of the platform devices 120₁-120_{R} are symmetric such that each platform device 120 is connected with each other platform device 120. In the example of FIG. 6, the platform device 120_{R} is a redundant platform device. While only a single redundant platform device is illustrated in FIG. 6, any number of redundant platform devices may be used.

The failure within the platform device 120₆ may occur before and/or during the emulation and verification process of a circuit design under test. For example, the platform devices 120₁-120₇ are configured via emulation data determined from the circuit design under test to perform one or more operations corresponding to the emulation and verification process and to communicate data between each other.

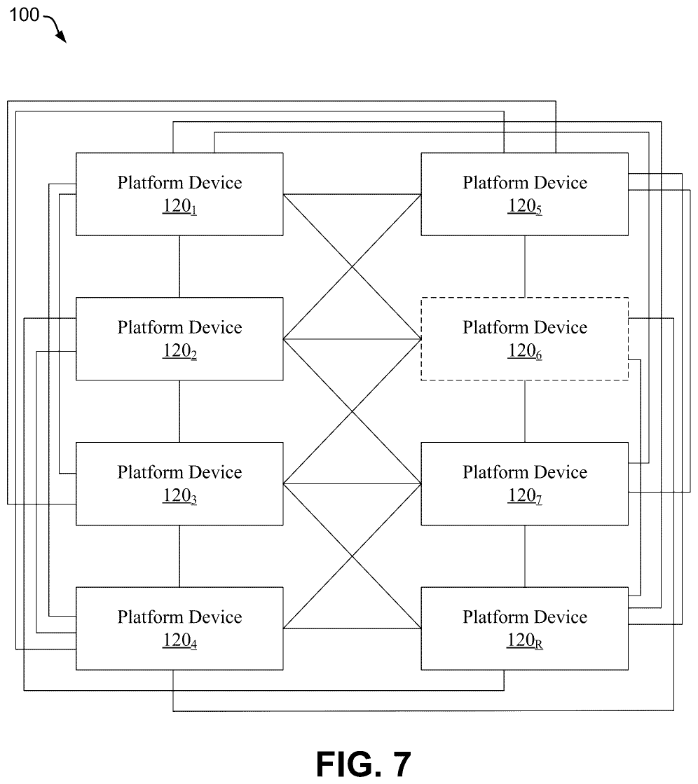

At 520 of the method 500, the failed platform device is disconnected from the other platform devices within the emulation system. As is illustrated in FIG. 7, the platform device 120₆ is disconnected from the other platform devices 120₁-120₅ and 120₇-120_{R} of the emulation system. In on example, the emulation and verification process is stopped to allow the failed platform device to be disconnected. To disconnect the failed platform device 120₆, the other platform devices 120 that are connected to the platform device 120₆ to perform the emulation and verification process are disconnected from the failed platform device 120₆. In one example, switching circuitry 132 within the interconnection circuitry 130, the platform devices 120, and/or the IC devices 122 is used to disconnect the failed platform device 120₆ from the other platform circuities.

In one example, the point at which or before the emulation and verification process is stopped is saved. Accordingly, the emulation and verification process may be restarted from when known good emulation and verification data is available, and the entire emulation and verification process does not have to be restarted.

At 530 of the method 500, the redundant platform device is connected in place of the failed platform device. For example with reference to FIG. 6, the redundant platform device 120_{R} is connected to the platform devices 120₁-120₅ and 120₇. In one example, switching circuitry 132 within the interconnection circuitry 130, the platform devices 120, and/or the IC devices 122 is used to connect the redundant platform device 120_{R} from the other platform circuities.

In one example, after the redundant platform device 120_{R} is connected to the platform devices 120₁-120₅ and 120₇, the emulation and verification process is completed. For example, the emulation and verification process may start from a saved point that is associated with last known good emulation and verification data. In another example, the emulation and verification process is restarted. However, as the platform devices 120 are symmetrically connected with each other, emulation and verification of the circuit design is performed after the detection of a failed platform and/or IC device without recompiling the circuit design, decreasing the emulation processing time and amount of time used to verify a circuit design. Stated another way, no additional updates are applied to the platform devices 120₁-120₅ and 120₇ other than connecting the platform devices with the platform device 120_{R} to continue and/or complete the emulation and verification process as the platform device 120_{R} function similar the failed platform device 120₆. In one example, to continue and/or complete the emulation and verification process, emulation data associated with the failed platform device 120₆ is provided and used to configure the redundant platform device 120_{R}. Accordingly, the redundant platform device 120_{R} performs the operations that had been applied to the failed platform device 120₆, and the emulation and verification process can be continued and/or completed. Using symmetric platform devices allows for the emulation and verification process can be completed in a shorter amount of time when failures occur, reducing the final manufacturing cost of the corresponding semiconductor device.

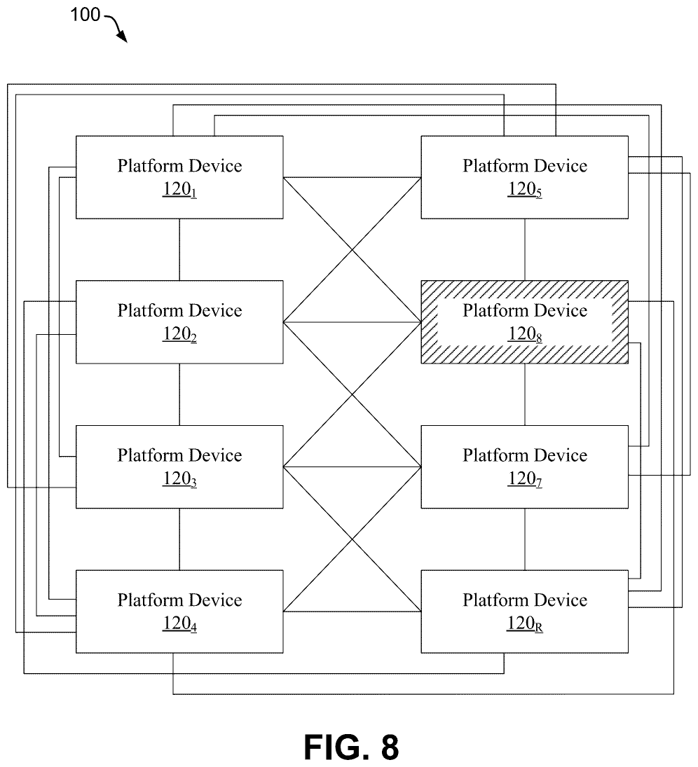

As is illustrated by FIG. 8, the failed platform device 120₆ is removed from the emulation system 100, and the platform device 120₈ is inserted within the emulation system 100. The platform device 120₈ connects to the same connections as the failed platform device 120₆ as the platform device 120₈ is configured the same as the failed platform device 120₆. For example, the platform device 120₈ is symmetrically connected to each of the platform devices 120 of the emulation system 100 using the same connections that were connected to the failed platform device 120₆. In the example of FIG. 8, the platform device 120_{R} is the redundant platform device.

While the method 500 of FIG. 5 is directed to detecting and mitigating a failed platform device 120, a similar process may be applied to detecting and mitigating a failed IC device 122. For example, at 510 of the method 500 a failed IC device 122 within a platform device 120 may detected. At 520 of the method 500, the failed IC device 122 is disconnected from the other IC devices within the same platform device 120 and the IC devices 122 of other platform devices 120. At 530 of the method 500, a redundant IC device 122 is connected in the place of the failed IC device 122. The redundant IC device 122 may be within the same platform device 120, another platform device 120, or a redundant platform device 120. As the each of the IC devices 122 are symmetrically connected to each other IC device 122 within the emulation system 100 and are configured the same way, the circuit design under test does not have to be recompiled when a redundant IC device 122 is used in place of the failed IC device 122. The redundant IC device(s) 122 perform the operations that had been applied to the failed IC device(s) 122, allowing the emulation and verification process can be continued and/or completed. Accordingly, the emulation and verification process can be completed in a shorter amount of time when failures occur, reducing the final manufacturing cost of the corresponding semiconductor device.

While the foregoing is directed to specific examples, other and further examples may be devised without departing from the basic scope thereof, and the scope thereof is determined by the claims that follow.

What is claimed is:

1. An emulation system comprising:
a first platform device comprising first integrated circuit (IC) devices, the first IC devices configured to emulate a circuit design for verification of the circuit design;
a second platform device comprising second IC devices; and
a processing device connected to the first platform device and the second platform device, the processing device configured to emulate the circuit design using one or more of the second IC devices based on a failure associated with the first platform device being detected.

2. The emulation system of claim 1 further comprising a third platform device having third IC devices, and wherein the first platform device is symmetrically connected to the second platform device and the third platform device.

3. The emulation system of claim 2, wherein the first IC devices are symmetrically connected with the second IC devices and the third IC devices.

4. The emulation system of claim 2, wherein the processing device is configured to disconnect the first platform device from the third platform device based on detecting the failure within the first platform device.

5. The emulation system of claim 4, wherein the processing device is further configured to connect the second platform device with the third platform device based on detecting the failure within the first platform device, and to perform emulation of the circuit design using the second platform device and the third platform device.

6. The emulation system of claim 5, wherein the processing device is further configured to provide emulation operations associated with the first platform device to the second platform device based on detecting the failure of the first platform device.

7. The emulation system of claim 1 further comprising interconnection circuitry comprising first optical connections that connect the first platform device with the second platform device.

8. The emulation system of claim 7, wherein the interconnection circuitry further comprises second optical connections that connect the first platform device with a third platform device, and third optical connections that connect the second platform device with the third platform device.

9. The emulation system of claim 1, wherein a number of the first IC devices is equal to a number of the second IC devices.

10. The emulation system of claim 1, wherein the processing device is configured to detect the failure associated with the first platform device.

11. The emulation system of claim 1 further comprising failure detection circuitry configured to detect the failure of the first platform device.

12. A method comprising:
detecting a failure in a first platform device of an emulation system, the emulation system configured to emulate a circuit design for verification of the circuit design;
disconnecting the first platform device from a second platform device of the emulation system based on detecting the failure; and
connecting the second platform device to a third platform device of the emulation system, wherein the circuit design is emulated using the second platform device and the third platform device.

13. The method of claim 12 wherein the first platform device is symmetrically connected to the second platform device and the third platform device.

14. The method of claim 13, wherein the first platform device comprises first integrated circuit (IC) devices that are symmetrically connected with second IC devices of the second platform device and third IC devices of the third platform device.

15. The method of claim 12, wherein the emulation of the circuit design using the first platform device is stopped based on detecting the failure of the first platform device.

16. The method of claim 12 further comprising providing emulation operations associated with the first platform device to the third platform device based on detecting the failure of the first platform device.

17. The method of claim 12 further comprising connecting a fourth platform device within the emulation system, wherein the fourth platform device is configured to function as a redundant platform device.

18. An emulation system comprising:
a first platform device;
a second platform device;
a third platform device;
interconnection circuitry that connects the first platform device, the second platform device, and the third platform device with each other; and
a processing device connected to the first platform device, the second platform device, and the third platform device, the processing device configured to:
perform a first emulation of a circuit design by outputting emulation data to the first platform device and the second platform device; and
stop the first emulation and perform a second emulation of the circuit design by outputting the emulation data to the second platform device and the third platform device based on a failure associated with the first platform device being detected.

19. The emulation system of claim 18, wherein the processing device is further configured to disconnect the first platform device from the second platform device, and connect the second platform device with the third platform device based on the failure associated with the first platform device being detected.

20. The emulation system of claim 18, wherein the first platform device comprises first integrated circuit (IC) devices, the second platform device comprises second IC devices, and the third platform device comprises third IC devices, and wherein the first IC devices, the second IC devices, and the third IC devices are symmetrically connected to each other via the interconnection circuitry.
